(19) United States
(12) Patent Application Publication
(10) Pub. No.: US 2013/0309785 A1
(43) Pub. Date: Nov. 21, 2013

(54) ROTATIONAL ABSORPTION SPECTRA FOR SEMICONDUCTOR MANUFACTURING PROCESS MONITORING AND CONTROL

(71) Applicant: Applied Material, Inc., Santa Clara, CA (US)

(72) Inventors: ZHIFENG SUI, Fremont, CA (US); MICHAEL D. ARMACOST, San Jose, CA (US); PHILLIP STOUT, Santa Clara, CA (US); LEI LIAN, Fremont, CA (US); RYAN PATZ, San Francisco, CA (US)

(73) Assignee: APPLIED MATERIALS, INC., Santa Clara, CA (US)

(21) Appl. No.: 13/868,318

(22) Filed: Apr. 23, 2013

Related U.S. Application Data
(60) Provisional application No. 61/648,934, filed on May 18, 2012.

(51) Int. Cl. H01L 21/66

(52) U.S. Cl. CPC H01L 22/10
USPC 438/14; 422/187

(57) ABSTRACT

Methods and apparatus for semiconductor manufacturing process monitoring and control are provided herein. In some embodiments, apparatus for substrate processing may include a process chamber for processing a substrate in an inner volume of the process chamber; a radiation source disposed outside of the process chamber to provide radiation at a frequency of about 200 GHz to about 2 THz into the inner volume via a dielectric window in a wall of the vacuum process chamber; a detector to detect the signal after having passed through the inner volume; and a controller coupled to the detector and configured to determine the composition of species within the inner volume based upon the detected signal.

### CROSS-REFERENCE TO RELATED APPLICATIONS

This application claims benefit of U.S. provisional patent application Ser. No. 61/648,934, filed May 18, 2012, which is herein incorporated by reference.

### FIELD

Embodiments of the present invention generally relate to semiconductor processing equipment, and more particularly, to methods and apparatus for semiconductor processing.

### BACKGROUND

Optical emission spectroscopy is one commonly used technique to detect the endpoint of certain semiconductor processes, such as a plasma etch process. For example, plasma transitions of reactant or product species emit photons which can be detected and used to determine the endpoint of a plasma process. The detected photons may be monitored and an endpoint determined based on increasing signal for reactants or decreasing signal for products. The endpoint is identified when either the reactants or products attain a specific concentration (i.e., the respective signals cross a threshold level).

However, as the device nodes and feature sizes of integrated circuits or other devices formed on a substrate continue to shrink, increased process control becomes more important. The inventors have observed that conventional optical emission spectroscopy, and other conventional endpoint detection techniques, may not provide the desired sensitivity to control substrate processes satisfactorily. For example, the signal provided by various species within a process chamber may overlap, undesirably providing a low signal to noise ratio that is undesirable for fine process control.

Thus, the inventors have provided improved apparatus and methods for semiconductor manufacturing process monitoring and control.

### SUMMARY

Methods and apparatus for semiconductor manufacturing process monitoring and control are provided herein. In some embodiments, apparatus for substrate processing may include a process chamber for processing a substrate in an inner volume of the process chamber; a radiation source disposed outside of the process chamber to provide radiation at a frequency between of about 200 GHz to about 2 THz into the inner volume via a dielectric window in a wall of the vacuum process chamber; a detector to detect the signal after having passed through the inner volume; and a controller coupled to the detector and configured to determine the composition of species within the inner volume based upon the detected signal.

In some embodiments, a method for monitoring a substrate process chamber may include performing a process in a process chamber; providing radiation at a frequency between of about 200 GHz to about 2 THz into an inner volume of the substrate process chamber; detecting the radiation after it has passed through the inner volume; and characterizing contents of the inner volume using a molecular rotational absorption intensity analysis on the detected radiation.

In some embodiments, the characterization may include one or more of controlling the process during the performance of the process, determining an endpoint of the process, fingerprinting the process chamber, matching the performance between the process chamber and a second process chamber used to perform the same process, or determining a fault in the performance of the process chamber.

In some embodiments, non-transitory computer readable medium having instructions stored thereon that when executed by a processor cause the processor to perform a method of monitoring a substrate process chamber may include performing a process in a process chamber, providing radiation into an inner volume of the substrate process chamber at a frequency of about 200 GHz to about 2 THz, detecting the radiation after it has passed through the inner volume, and characterizing contents of the inner volume using a molecular rotational absorption intensity analysis on the detected radiation.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 is a schematic side view of a substrate processing system in accordance with some embodiments of the present invention.

FIG. 2 is a flow chart of a method for monitoring a substrate processing chamber in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention provide methods and apparatus for using molecular rotational absorption spectra to diagnose the health of semiconductor manufacturing processes. Non-limiting examples of suitable semiconductor manufacturing processes include vacuum processes, plasma enhanced vacuum processes, and the like.

Rotational spectrum from a molecule (to first order) requires that the molecule have a dipole moment and that there be a difference between its center of charge and its center of mass, or equivalently a separation between two unlike charges. It is this dipole moment that enables the electric field of the electromagnetic radiation to exert a torque on the molecule, causing it to rotate more quickly (in excitation) or slowly (in de-excitation). The frequency range of interest is defined by the frequency bands where molecules have a rotational spectral response. In some embodiments, this frequency range may be about 200 GHz to about 2 THz. In other embodiments, the frequency range may be a wider range from about 10 GHz to about 2 THz. This is a new and unexplored portion of the spectrum that is rich in unique molecular information for characterizing semiconductor manufacturing processes.

For example, plasma etch chemistry is quite complicated. In the case of dielectric etch, fluorocarbon gas chemistry is used to etch the dielectric materials, such as SiO₂, and SiN, and the like. The etch plasma chemistry includes the reactant gas molecule fragments, such as CF, CF₂, CF₃, C₂F₂, etc., and the etchant gas molecule fragments. Knowing the fraction of each fragment as precisely as possible facilitates better understanding of the makeup of the process recipe being used. This knowledge can be used to match performance of the etch chambers. The methods of monitoring and using information obtained from the molecular rotational absorption spectra in accordance with embodiments of the present invention can provide this useful information.

Since actual densities and temperatures within the plasma are being measured, plasma processes may be controlled using the measured densities and temperatures as the set points, as compared to conventional use of RF power, chamber pressure, gas flow, etc. For example, in some embodiments, instead of setting chamber pressure, RF power, gas flow, and the like typical process parameters conventionally used to control a semiconductor substrate process, the process may instead be controlled to target species densities, species temperatures, and chamber setting ranges. Chamber settings may include process parameters such as RF power, or the like, that can vary within a predefined range instead of being retained at a fixed value during the process. For example, chamber setting ranges can set an upper and lower bound to what the power or other variable process parameter can be changed to during a particular process. Defining chamber setting ranges can advantageously provide process flexibility while preventing runaway processes. Then, the power, pressure, flow, etc., may be determined from models or calculations of chamber behavior. Settings for performing a particular process on a substrate may be based on measured density and temperature deviations from targets and may vary within operational windows set up in a process recipe for performing the particular process in the process chamber. In this manner, the process is controlling to a desired measured plasma above the substrate. For different chambers that may result in slightly different power, pressure, flow, and the like operating conditions for each respective chamber to achieve the desired species targets. This approach advantageously allows for variation in plasma generation among different chambers while achieving better on-substrate results.

Examples of uses of the inventive apparatus include using molecular rotational absorption intensity to perform the endpoint detection for substrate processes, such as in plasma etch chambers, using molecular rotational absorption spectral intensity to fingerprint a plasma process chamber and to match the performance between chambers used for the same process, using molecular rotational absorption spectral intensity to perform fault detection for a semiconductor process chamber.

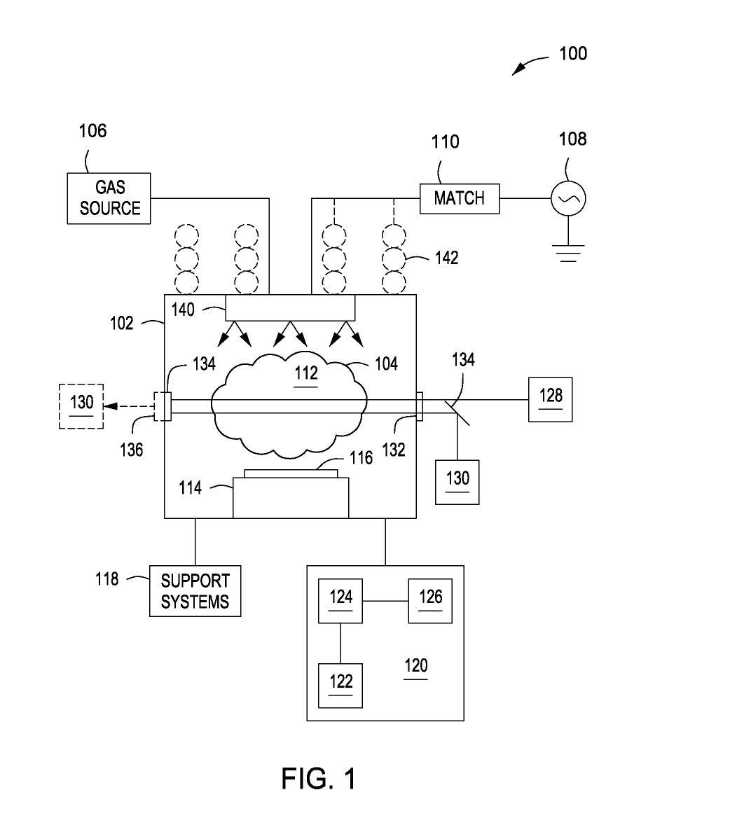

For example, FIG. 1 is a schematic side view of a substrate processing system 100 in accordance with some embodiments of the present invention. The substrate processing system 100 may generally include a substrate process chamber 102 having an inner volume 104. A gas source 106 may be fluidly coupled to the inner volume 104 to provide one or more gases to the inner volume, for example, to process the substrate, clean the inner volume facing surfaces of the process chamber, or the like. The gas source 106 may be fluidly coupled to the inner volume 104 in any suitable manner, such as by gas inlets, showerheads, nozzles, or the like. A showerhead 140 is illustratively shown in FIG. 1.

In some embodiments, a radio frequency (RF) power supply 108 may be operatively coupled to the process chamber 102 to provide a RF energy sufficient to form and/or maintain a plasma 112 within the inner volume 104. A match circuit 110 may be provided along the RF transmission line to the chamber to minimize any RF energy reflected back to the RF power supply 108. The RF power supply 108 may be coupled to the chamber in any suitable manner, such as capacitively coupled (as shown), inductively coupled (as shown in phantom), or the like. In some embodiments, the RF power supply 108 may be inductively coupled to the chamber via one or more concentric coils 142.

A substrate support 114 is disposed within the inner volume 104 of the process chamber 102 to support a substrate 116 thereon. The substrate may generally be any suitable substrate used in vacuum processes, such as, semiconductor wafers, glass panels, or the like.

Support systems 118 include components used to facilitate performing pre-determined processes in the process chamber 102. Such components generally include various sub-systems (e.g., gas panel(s), gas distribution conduits, vacuum and exhaust sub-systems, and the like) and devices (e.g., power supplies, process control instruments, and the like) of the process chamber 102.

A controller 120 may be provided to facilitate control of the substrate processing system 100 in the manner as described herein. The controller 120 generally comprises a central processing unit (CPU) 122, a memory 124, and support circuits 126 and is coupled to and controls the process chamber 102 and support systems 118, directly or, alternatively, via other computers (or controllers) associated with the process chamber and/or the support systems. The CPU 122 may be of any form of a general-purpose computer processor used in an industrial setting. Software routines can be stored in the memory 124, such as random access memory, read only memory, floppy or hard disk, or other form of digital storage, local or remote. The support circuits 126 are conventionally coupled to the CPU 122 and may comprise cache, clock circuits, input/output sub-systems, power supplies, and the like. The software routines, when executed by the CPU 122, transform the CPU into a specific purpose computer (controller) 120 that controls the substrate processing system 100 such that the processes are performed in accordance with the present invention. The software routines may also be stored and/or executed by a second controller that is located remotely from the substrate processing system 100.

A radiation source 128 is provided to transmit radiation with frequency range between a few hundred GHz to low THz. For example, in some embodiments, this frequency range may be about 200 GHz to about 2 THz. In other embodiments, the frequency range may be a wider range from about 10 GHz to about 2 THz. Radiation provided at these frequencies advantageously facilitates obtaining quantitative species information including all polar species within the process chamber: radical, neutral, or ion. In addition, low temperature plasmas typically used in substrate processing do not generate radiation having these frequencies, thereby advantageously providing a low noise environment (i.e., allowing for a high signal to noise ratio to be established). The radiation may be provided to the inner volume 104 of the process chamber 102 via a dielectric window 132 that is transparent to the radiation. In some embodiments, the radiation source 128 may comprise an RF source and associated circuitry to double the frequency of the RF energy multiple times to obtain the desired frequency. In some embodiments, the RF source may be a frequency tuned RF source capable of providing RF energy at a range of frequencies, such that multiple desired frequencies can be provided without requiring a different radiation source 128.

A detector 130 is provided to receive the radiation after it has traveled through the inner volume 104. The detector 130 is configured to detect the intensity of the radiation after it has traveled through the inner volume 104 (i.e., after some of the radiation has been absorbed by species within the inner volume 104). The detector 130 sends data to the controller 120 (or to some other controller) representative of the intensity of the radiation over a band of frequencies such that the contents of the inner volume 104 may be characterized, as discussed in more detail below.

The position of the radiation source 128 and the detector 130 may vary. For example, the radiation source 128 and the detector 130 may be configured to transmit and receive the radiation through the same dielectric window 132. In such embodiments, the radiation may reflect off of the opposing chamber wall, or one or more reflectors 134 may be provided to enhance quantity of reflected radiation. Alternatively, the radiation source 128 and the detector 130 may be configured to transmit and receive the radiation through different dielectric windows 132. For example, the radiation source 128 and the detector 130 may be disposed on opposite sides of the process chamber 102 (as shown in phantom in FIG. 1), or in some other location, and a second dielectric window 136 may be provided to allow the radiation to exit the process chamber 102. Where there is no direct line of sight, the radiation may reflect off of one or more chamber wall surfaces and/or reflectors 134 to travel from the radiation source 128 to the detector 130. The reflectors 134 may be fabricated from any suitable material for reflecting the range of wavelengths of the radiation produced by the radiation source 128. In addition, the reflectors 134 may be fabricated from any suitable material for use in or about a process chamber that can withstand the process chamber operating environment and be easily cleaned.

Although FIG. 1 shows radiation source 128 providing radiation horizontally with respect to the substrate 116, in some embodiments, radiation source 128 may provide radiation perpendicular to the substrate 116 and use the reflectors 134 to direct the radiation through the process chamber as desired. In other embodiments, radiation source 128 may provide radiation perpendicular to the substrate 116 such that the radiation reflects off the substrate 116.

Advantageously, due to the range of frequencies used, the present invention does not require a high quality reflection in order to operate, due, for example, to the low noise environment providing a high signal to noise ratio. For example, the chamber wall surfaces or the one or more reflectors may become dirty over time due to their position within the process chamber while still being operational, as compared to prior art apparatus and techniques where clean and highly reflective surfaces may be required.

The position of the radiation source 128 and the detector 130 may be selected to provide a desired quality signal (i.e., sufficient to characterize the chamber contents). For example, the one or more dielectric windows 132 (or 136) may be provided in a main body of the chamber, in a source region near where the plasma is formed, in a pump port region where the chamber contents are exhausted, or the like. Multiple reflectors 134 may be provided to cause the radiation to pass across the inner volume multiple times to improve the reliability of the data obtained from the radiation detected by the detector 130.

Using the data representative of the intensity of the radiation obtained by the detector 130, various characterizations of the contents of the chamber may be obtained. Such characterization may be used to control the processes being performed in the process chamber 102, to monitor the state of the process chamber 102, or to match the performance of the process chamber 102 to a different process chamber 102 that may be performing the same processes.

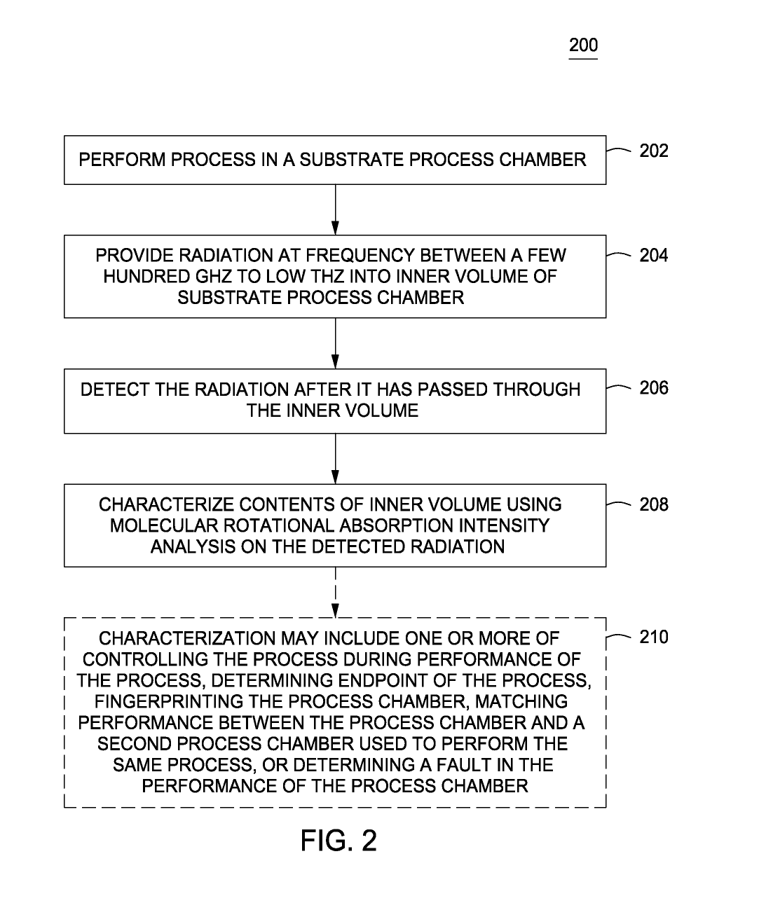

For example, FIG. 2 depicts a flow chart of a method 200 for monitoring a substrate process chamber in accordance with some embodiments of the present invention. The method 200 may be performed in any suitable substrate processing system, such as the illustrative substrate processing system 100 described above. In some embodiments, the method 200 may begin at 202, where a process may be performed in a process chamber. The method may be any process typically performed in substrate processing, such as etching, deposition, or the like. Next, at 204, radiation may be provided into an inner volume of the substrate process chamber at a frequency of about few hundred GHz to low THz into an inner volume of the substrate process chamber (e.g., at a frequency to provide molecular information of species within the inner volume). At 206, the radiation is detected after it has passed through the inner volume. At 208, contents of the inner volume may be characterized using a molecular rotational absorption intensity analysis on the detected radiation.

In some embodiments, as shown at 210, the characterization of the inner volume at 208 may include one or more of controlling the process during the performance of the process, determining an endpoint of the process, fingerprinting the process chamber, matching the performance between the process chamber and a second process chamber used to perform the same process, or determining a fault in the performance of the process chamber.

While the foregoing is directed to embodiments of the present invention, other and further embodiments of the invention may be devised without departing from the basic scope thereof.

1. Apparatus for substrate processing, comprising:
a process chamber for processing a substrate in an inner volume of the process chamber;
a radiation source disposed outside of the process chamber to provide radiation at a frequency of about 200 GHz to about 2 THz into the inner volume via a dielectric window in a wall of the vacuum process chamber;
a detector to detect the signal after having passed through the inner volume; and
a controller coupled to the detector and configured to determine the composition of species within the inner volume based upon the detected signal.

2. The apparatus of claim 1, further comprising:
a gas source to provide one or more gases to the inner volume;
an RF source to provide RF energy to the inner volume to form a plasma from the one or more gases provided to the inner volume.

3. The apparatus of claim 1, further comprising:
one or more reflectors disposed within the inner volume to reflect the signal from the radiation source to the detector.

4. The apparatus of claim 1, wherein the detector is configured to detect an intensity of the radiation after it has traveled through the inner volume.

5. The apparatus of claim 1, wherein the frequency of the radiation selected provides molecular information of species within the inner volume.

6. A method for monitoring a substrate process chamber, comprising:
performing a process in a process chamber;
providing radiation at a frequency of about 200 GHz to about 2 THz into an inner volume of the substrate process chamber;
detecting the radiation after it has passed through the inner volume; and
characterizing contents of the inner volume using a molecular rotational absorption intensity analysis on the detected radiation.

7. The method of claim 6, wherein the characterization includes controlling the process during the performance of the process.

8. The method of claim 6, wherein the characterization includes determining an endpoint of the process.

9. The method of claim 6, wherein the characterization includes fingerprinting the process chamber.

10. The method of claim 6, wherein the characterization includes matching the performance between the process chamber and a second process chamber used to perform the same process.

11. The method of claim 6, wherein the characterization includes determining a fault in the performance of the process chamber.

12. The method of claim 6, wherein providing radiation at said frequencies facilitates obtaining quantitative species information including one or more polar species within the process chamber.

13. The method of claim 12, wherein the one or more polar species within the process chamber include radical, neutral, or ion species.

14. The method of claim 6, wherein the frequency of the radiation used is different than a frequency of radiation generated by a plasma used in the process chamber.

15. The method of any of claim 6, wherein the process performed is one of an etch process or a deposition process.

16. The method of claim 6, wherein the frequency of the radiation selected provides molecular information of species within the inner volume.

17. A non-transitory computer readable medium having instructions stored thereon that when executed by a processor cause the processor to perform a method of monitoring a substrate process chamber, comprising:
performing a process in a process chamber;
providing radiation into an inner volume of the substrate process chamber at a frequency of about 200 GHz to about 2 THz;
detecting the radiation after it has passed through the inner volume; and
characterizing contents of the inner volume using a molecular rotational absorption intensity analysis on the detected radiation.

18. The non-transitory computer readable medium of claim 17, wherein the frequency of the radiation selected provides molecular information of species within the inner volume.

19. The non-transitory computer readable medium of claim 17, wherein the characterization includes at least one of controlling the process during the performance of the process, determining an endpoint of the process, fingerprinting the process chamber, matching the performance between the process chamber and a second process chamber used to perform the same process, or determining a fault in the performance of the process chamber.

20. The non-transitory computer readable medium of claim 17, wherein providing radiation at said frequencies facilitates obtaining quantitative species information including one or more polar species within the process chamber.
